(19) United States
(12) Patent Application Publication
(10) Pub. No.: US 2018/0286564 A1
(43) Pub. Date: Oct. 4, 2018

(54) POWER CONVERTER MODULE

(71) Applicant: SIEMENS AKTIENGESELLSCHAFT, München (DE)

(72) Inventors: Wolfgang Feil, Schwandorf (DE); Martin Maier, Erbendorf (DE); Uwe Weiss, Amberg (DE)

(21) Appl. No.: 15/764,473

(22) PCT Filed: Aug. 8, 2016
(86) PCT No.: PCT/EP2016/068847

§ 371 Date: Mar. 29, 2018

(30) Foreign Application Priority Data
Sep. 29, 2015 (DE) 10 2015 218 715.2

(51) Int. Cl. H01F 27/28; H01F 27/245; H01F 27/25; H01F 27/26; H01F 38/30

(52) U.S. Cl. CPC H01F 27/2804; H01F 27/245; H01F 27/25; H05K 2201/083; H01F 38/30; H01F 2027/2819; H01F 2027/2809; H01F 27/266

(57) ABSTRACT

The invention relates to a power converter module comprising a circuit board (7) in which an iron core (1) is integrated in recesses (6) of the circuit board (7), a winding with windings, forming a secondary circuit (8) of the power converter module, is arranged in or on the circuit board (7).

This application is the National Stage of International Application No. PCT/EP2016/068847, filed Aug. 8, 2016, which claims the benefit of German Patent Application No. 10 2015 218 715.2, filed Sep. 29, 2015. The entire contents of these documents are hereby incorporated herein by reference.

### BACKGROUND

The present embodiments relate to a power converter module.

Power converters of the annular core converter type are known. A secondary circuit of such a power converter typically includes a ring winding (e.g., an annular core). The primary circuit of the power converter includes a wire that passes through the ring winding. In accordance with statutory requirements, the design of the power converter is required to comply with predefined clearances and creepage distances between the primary- and secondary-side terminals or between the primary-side terminal and the ring winding. The ring winding is typically formed by enameled wire that, for the purposes of statutory requirements, is not classified as insulated. Conversely, the constituent wire of the primary circuit is generally sufficiently insulated. Specific minimum clearances are to be observed between the insulation-stripped free ends of the primary circuit wire and the ring winding.

In addition to this type of annular core converter, converters that are formed by alternately-coated plates with a coil former also exist. The coil former provides an advantage in that the coil former may be simply and rapidly wound. However, the coil former is associated with one-off tooling costs. Overall, however, the accuracy and the dynamic range are poorer in this type of converter than in an annular core converter.

The above-mentioned examples of a power converter have a number of disadvantages. The fitting of the secondary windings involves a substantial degree of complexity. It is further necessary to fit terminal leads that are to be bonded with the circuit board. In the event of the separation of the power converter subassembly from the circuit board, more space is required.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a power converter module that overcomes the above-mentioned disadvantages in a simple manner is provided.

According to an embodiment, a power converter module includes a circuit board, in which an iron circuit is integrated in recesses of the circuit board. A winding, with turns, forming a secondary circuit of the power converter module, is arranged in or on the circuit board.

The power converter module may be a power converter of modular design (e.g., without an own housing), the primary and secondary circuits of which are integrated in or on the circuit board.

The present embodiments incorporate a circuit board, upon and in which the secondary windings are configured as printed conductors. The circuit board incorporates recesses for the accommodation of an iron circuit. The primary windings may be configured as separate conductors or as printed conductors formed upon and in the circuit board layers.

In a configuration of the present embodiments, the iron circuit is configured of plates (e.g., U-, E- or L-section plates), an annular strip, ferromagnetic half-shells, or cut strip-wound core halves. Individually stacked U-section plates are configured in a mutually alternating arrangement. This design thus incorporates virtually no air gap. The annular strip provides an advantage in that the magnetic flux may be guided in an optimum manner. The ferromagnetic half-shells provide an advantage in that the two half-shells permit a simple assembly, and the properties of the air gap may be controlled by the overlapping surfaces. On the grounds of the two-part structure, the cut strip-wound core halves also permit simple assembly. The cut strip-wound core halves have mutual joining to form a closed iron circuit.

In another development of the present embodiments, the iron circuit is accommodated in a recess or a plurality of recesses in the circuit board, and the constituent turns of the secondary circuit are routed through the iron circuit. By the recesses in the circuit board, the secure attachment of the iron circuit is achieved. The respective iron circuit incorporates two shank elements, which are interconnected by a connecting section. The secondary circuit is wound into and upon the circuit board around one of the two shank elements.

In a configuration of the present embodiments, the constituent turns of the secondary circuit are configured on a plurality of circuit board layers. In order to achieve a technologically significant number of turns, the turns are to be distributed over a plurality of layers in a circuit board.

In another development of the present embodiments, the circuit board layers, configured with the constituent turns of the secondary circuit, are configured with through-contacts between the circuit board layers through the entire circuit board. This is particularly cost-effective.

In another development of the present embodiments, the circuit board layers, configured with the constituent turns of the secondary circuit, are configured with through-contacts between the layers only in sub-regions of the circuit board. In order to avoid the enlargement of clearances between turns, through-contacts are thus arranged outside the actual winding surface.

In another development of the present embodiments, the through-contacts are arranged outside the winding surface of the constituent turns of the secondary circuit. This is associated with the advantage, whereby it is not necessary to enlarge the clearances between turns.

In a configuration of the present embodiments, the power converter module is configured for motor protection.

In a configuration of the present embodiments, the power converter module is configured for line protection.

In another development of the present embodiments, the power converter module is configured with a 3-phase design including three iron circuits and three secondary circuits that are electrically interconnected.

The power converter module according to one or more of the present embodiments incorporates an iron circuit that may be formed by U-section plates, cut strip-wound core halves, an annular strip, or ferromagnetic half-shells. The iron circuit is accommodated in recesses in a circuit board. The recesses in the circuit board may be arranged in mutual opposition. The respective form of embodiment of the iron circuit, in each embodiment, incorporates two shank elements that are interconnected by a connecting section. The shank elements of the respective iron circuit are positioned in recesses in the circuit board. A winding of the power converter module, constituting a secondary circuit and including a plurality of turns, is configured on the circuit board around a respective shank element of the iron circuit.

### BRIEF DESCRIPTION OF THE DRAWINGS

FIG. 1 shows an exemplary embodiment of a power converter module with an iron circuit in the form of U-section plates;

FIG. 2 shows a further exemplary embodiment of a power converter module with an iron circuit in the form of cut strip-wound core halves;

FIG. 3 shows a further exemplary embodiment of a power converter module with an iron circuit in the form of an annular strip;

FIG. 4 shows a further exemplary embodiment of a power converter module with an iron circuit in the form of ferromagnetic half-shells;

FIG. 5 shows an exemplary embodiment of the power converter module of FIG. 4, where the ferromagnetic half-shells are formed of stacked plates;

FIG. 6 shows one embodiment of a coil with through-contacts through the full circuit board layers; and

FIG. 7 shows one embodiment of a coil with through-contacts between individual layers of a circuit board.

### DETAILED DESCRIPTION

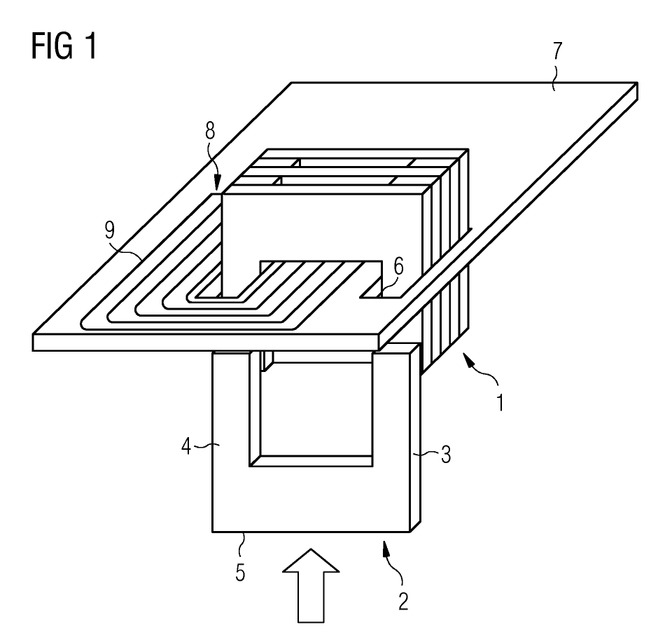

FIG. 1 shows an exemplary embodiment of a power converter module. The power converter module includes an iron circuit 1 that may be constituted of U-section plates 2. The U-section plates 2 incorporate two (e.g., mutually opposing) shank elements 3, 4 that are interconnected by a connecting section 5. The iron circuit 1 is accommodated in recesses 6 in a circuit board 7. The recesses 6 in the circuit board 7 may be arranged in mutual opposition. The shank elements 3, 4 of the plates of U-section design are positioned in the recesses 6 in the circuit board 7. The U-section plates 2 may be arranged with an exposed side alternately above or below the circuit board 7. The direction represented by the arrow in FIG. 1 is the direction of installation. A winding of the power converter module, constituting a secondary circuit 8 and including a plurality of turns 9, is configured on the circuit board 7 around a respective shank element of the iron circuit 1.

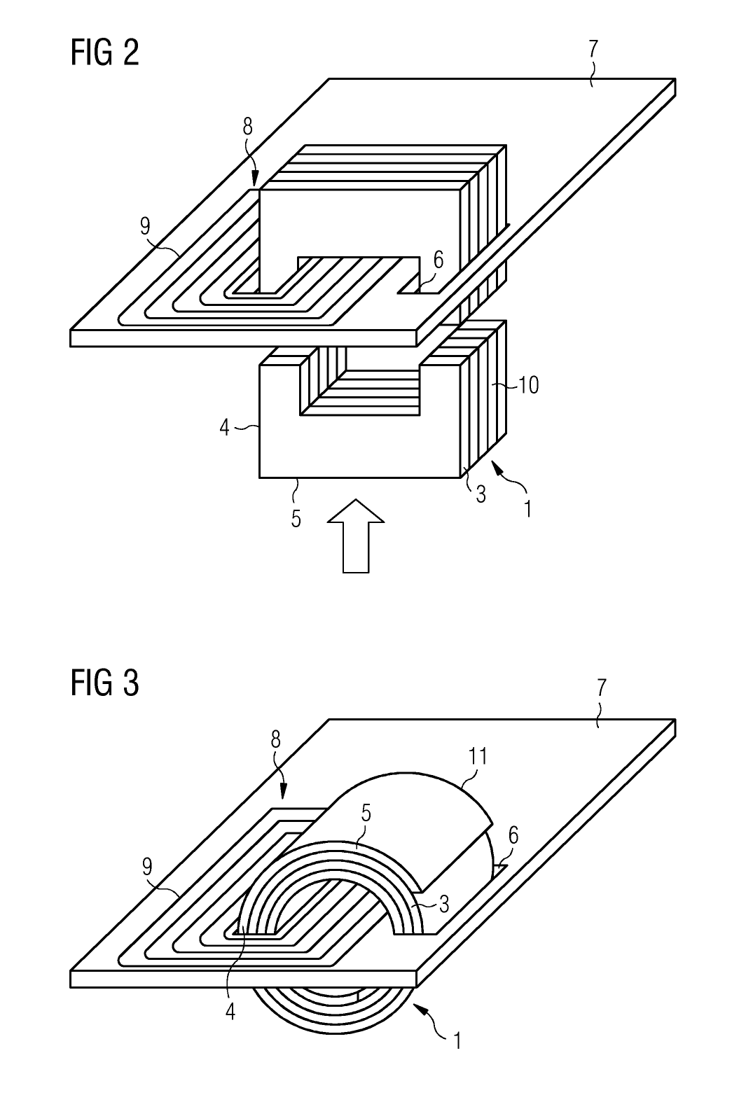

FIG. 2 represents a further exemplary embodiment of a power converter module according to one or more of the present embodiments. In this case, the iron core 1 is configured in the form of cut strip-wound core halves 10. The cut strip-wound core halves 10 are of U-section design and include two mutually opposing shank elements 3, 4 and a connecting section 5. The shank elements 3, 4 of the cut strip-wound core halves 10 of U-section design are positioned in the recesses 6 in the circuit board 7, where an iron circuit 1 is constituted by the cut strip-wound core halves 10 in combination. A winding of the power converter module, constituting a secondary circuit 8 and including a plurality of turns 9, is configured on the circuit board 7 around a respective shank element of the iron circuit 1.

FIG. 3 shows a further exemplary embodiment of a power converter module according to one or more of the present embodiments, with an iron circuit 1 in the form of an annular strip 11. The annular strip 11 is wound through the recesses 6 in the circuit board 7, and thus constitutes a cylinder. As a result of this cylindrical configuration, the shank elements 3, 4 and the connecting section 5 are arranged in a mutually continuous configuration. A winding of the power converter module, constituting a secondary circuit 8 and including a plurality of turns 9, is configured on the circuit board 7 around a respective shank element of the iron circuit 1.

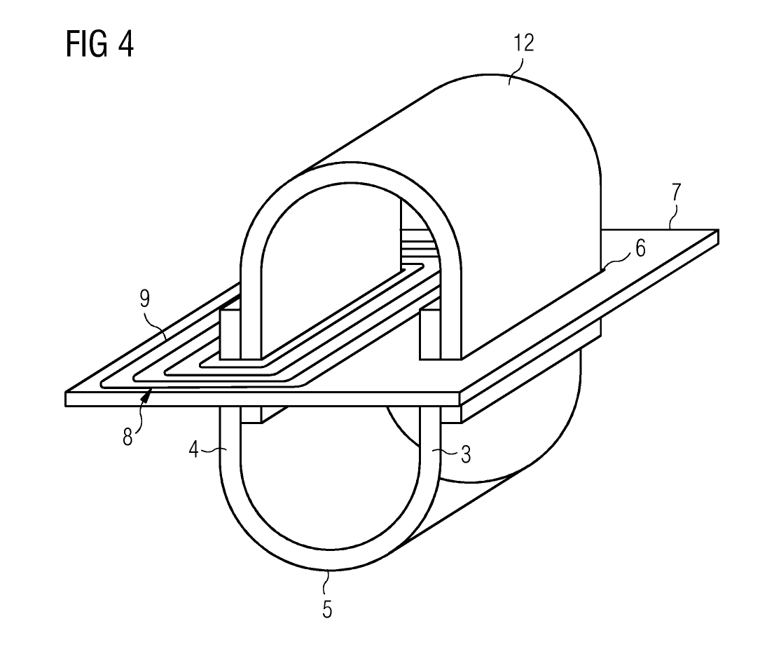

FIG. 4 shows a further exemplary embodiment of a power converter module according to one or more of the present embodiments, with an iron circuit 1 in the form of ferromagnetic half-shells 12. The ferromagnetic half-shells 12 are of U-section design and include two mutually opposing shank elements 3, 4 and a connecting section 5. The shank elements 3, 4 of the ferromagnetic half-shells 12 of U-section design are positioned in the recesses 6 in the circuit board 7, where the ferromagnetic half-shells 12 are configured in a mutually offset arrangement, such that a connecting section 5 of the U-section ferromagnetic half-shells 12 is arranged both above and below the circuit board 7. A winding of the power converter module, constituting a secondary circuit 8 and including a plurality of turns 9, is configured on the circuit board 7 around a respective shank element of the iron circuit 1.

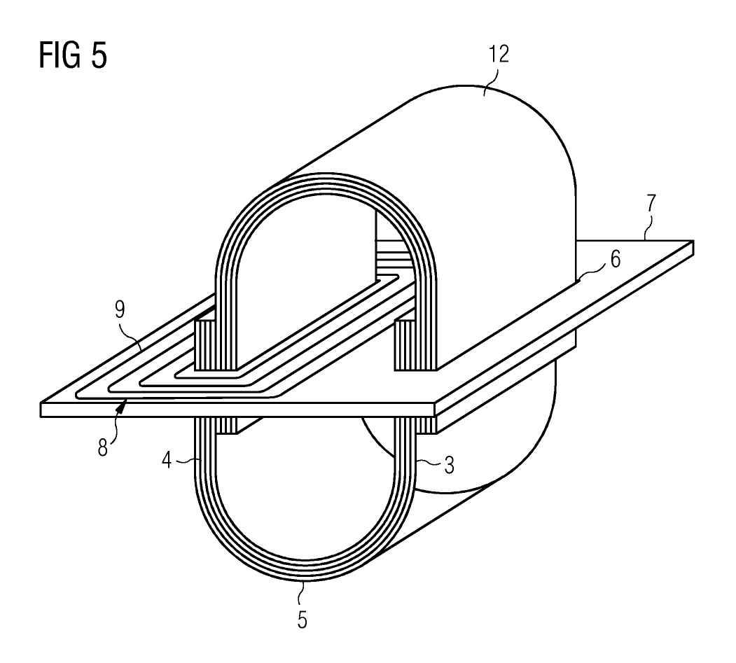

FIG. 5 shows the exemplary embodiment according to FIG. 4, where the ferromagnetic half-shells 12 are constituted of stacked plates.

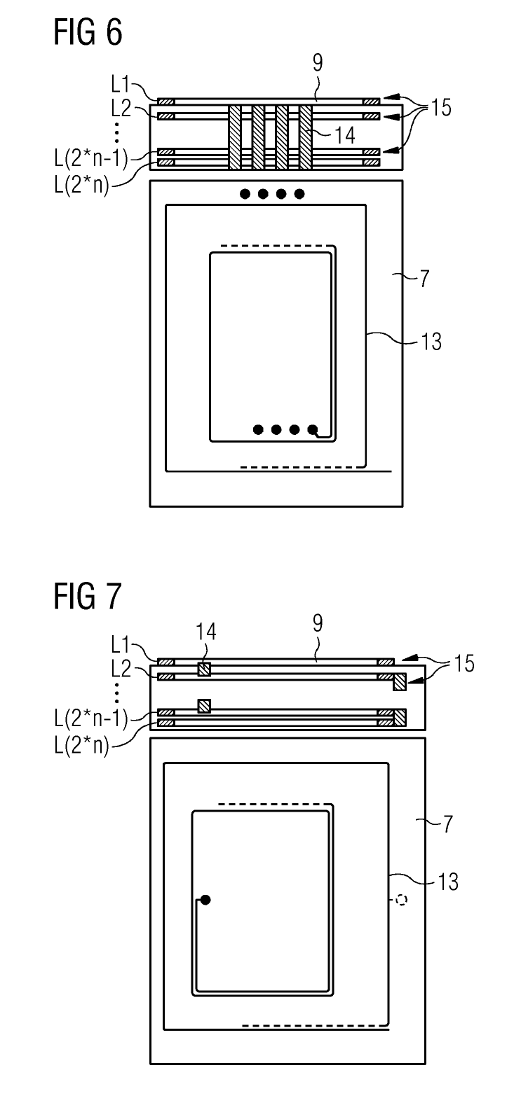

FIG. 6 shows a coil 13 with turns 9, and with through-contacts 14 through the full circuit board layers 15. In addition to the optimum design of the iron circuit 1, the optimum arrangement of the secondary winding on the circuit board 7 may be achieved. In order to achieve a technologically significant number of turns 9, the turns 9 are to be distributed over a plurality of layers in a circuit board. These circuit board layers 15 are to be interconnected by through-contacts 14. As the turns 9 in the individual circuit board layers 15 may be routed alternately from the interior to the exterior, then back again from the exterior to the interior, the through-contacts 14 are thus arranged alternately on the interior and the exterior. Interior through-contacts 14 may occupy as little circuit board space as possible, and may thus be oriented in a single line to the end face of the iron plate stack.

FIG. 7 shows a coil 13 with turns 9, with through-contacts 14 between individual layers of a circuit board 7. In one embodiment, the through-contacts 14 are arranged outside the actual winding surface in order to avoid the enlargement of clearances between the turns. An optimum solution with respect to structural space is achieved if through-contacts 14 with odd and even numbers are arranged in direct respective positional opposition to each other.

For both of the options represented in FIG. 6 and FIG. 7, an even number of circuit board layers 15 may be employed, as both the turn ends of the through-contacted coil 13 will then be automatically arranged on the exterior.

The power converter module according to one or more of the present embodiments is characterized in that the complex separate application of the secondary turns to the iron circuit may be omitted, as the turns are integrated in the circuit board. By the integration of the secondary turns in the circuit board, no fitting of terminal leads to the circuit board is required, and likewise, bonding of the terminal leads to the circuit board is required. By the integration of the iron circuit in the circuit board, a significantly more compact design is achieved in the power converter module according to one or more of the present embodiments, with a reduced space requirement, in comparison with the prior art.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A power converter module comprising:
a circuit board, in which an iron circuit is integrated in at least one recess of the circuit board,
wherein a winding, with turns, forming a secondary circuit of the power converter module, is arranged in or on the circuit board.

2. The power converter module of claim 1, wherein the iron circuit is configured of plates, cut strip-wound core halves, an annular strip, or ferromagnetic half-shells.

3. The power converter module of claim 1, wherein the iron circuit is accommodated in a recess of the at least one recess or a plurality of recesses of the at least one recess in the circuit board, and constituent turns of the secondary circuit are routed through the iron circuit.

4. The power converter module of claim 1, wherein constituent turns of the secondary circuit are configured on a plurality of circuit board layers of the circuit board.

5. The power converter module of claim 4, wherein the plurality of circuit board layers, configured with the constituent turns of the secondary circuit, are configured with through-contacts between the plurality of circuit board layers through the entire circuit board.

6. The power converter module of claim 4, wherein the plurality of circuit board layers, configured with the constituent turns of the secondary circuit, are configured with through-contacts only in sub regions of the plurality of circuit-board layers of the circuit board.

7. The power converter module of claim 6, wherein the through-contacts are arranged outside a winding surface of the constituent turns of the secondary circuit.

8. The power converter module of claim 1, wherein the power converter module is configured for motor protection.

9. The power converter module of claim 1, wherein the power converter module is configured for line protection.

10. The power converter module of claim 1, wherein the power converter module is configured with a 3-phase design,
wherein the iron circuit is a first iron circuit, and the secondary circuit is a first secondary circuit,
wherein the power converter module further comprises a second iron circuit, a third iron circuit, a second secondary circuit, and a third secondary circuit, and
wherein the first iron circuit, the second iron circuit, the third iron circuit, the first secondary circuit, the second secondary circuit, and the third secondary circuit are electrically interconnected.

11. The power converter module of claim 1, wherein the iron circuit is configured of U-, E- or L-section plates.

12. The power converter module of claim 2, wherein the iron circuit is accommodated in a recess of the at least one recess or a plurality of recesses of the at least one recess in the circuit board, and constituent turns of the secondary circuit are routed through the iron circuit.

13. The power converter module of claim 2, wherein constituent turns of the secondary circuit are configured on a plurality of circuit board layers of the circuit board.

14. The power converter module of claim 3, wherein constituent turns of the secondary circuit are configured on a plurality of circuit board layers of the circuit board.

15. The power converter module of claim 13, wherein the plurality of circuit board layers, configured with the constituent turns of the secondary circuit, are configured with through-contacts between the plurality of circuit board layers through the entire circuit board.

16. The power converter module of claim 14, wherein the plurality of circuit board layers, configured with the constituent turns of the secondary circuit, are configured with through-contacts between the plurality of circuit board layers through the entire circuit board.

17. The power converter module of claim 13, wherein the plurality of circuit board layers, configured with the constituent turns of the secondary circuit, are configured with through-contacts only in sub regions of the plurality of circuit-board layers of the circuit board.

18. The power converter module of claim 14, wherein the plurality of circuit board layers, configured with the constituent turns of the secondary circuit, are configured with through-contacts only in sub regions of the plurality of circuit-board layers of the circuit board.

19. The power converter module of claim 17, wherein the through-contacts are arranged outside a winding surface of the constituent turns of the secondary circuit.

20. The power converter module of claim 18, wherein the through-contacts are arranged outside a winding surface of the constituent turns of the secondary circuit.
